(19) United States
(12) Patent Application Publication
(10) Pub. No.: US 2026/0344520 A1
(43) Pub. Date: Oct. 29, 2026

(54) PACKAGING ARCHITECTURE FOR WAFER-SCALE KNOWN-GOOD-DIE TO KNOWN-GOOD-DIE HYBRID BONDING

(71) Applicant: Intel Foundry IP LLC, Santa Clara, CA (US)

(72) Inventors: Omkar G. Karhade, Chandler, AZ (US); Nitin A. Deshpande, Chandler, AZ (US); Debendra Mallik, Chandler, AZ (US); Steve Cho, Chandler, AZ (US); Babak Sabi, Portland, OR (US)

(73) Assignee: Intel Foundry IP LLC, Santa Clara, CA (US)

(21) Appl. No.: 19/719,333

(22) Filed: Jun. 25, 2026

Related U.S. Application Data
(63) Continuation of application No. 17/728,147, filed on Apr. 25, 2022.

(51) Int. Cl. H10W 90/00; H10P 54/00; H10W 20/42; H10W 72/00; H10W 72/20

(52) U.S. Cl. CPC H10W 90/00; H10P 54/00; H10W 20/42; H10W 72/0198; H10W 72/20; H10W 72/252; H10W 90/792

(57) ABSTRACT

Embodiments of a microelectronic assembly comprise a microelectronic assembly, comprising: a stack of layers coupled by at least fusion bonds; a package substrate coupled to a first layer in the stack of layers; one or more dies in the first layer; and one or more dies in a second layer in the stack of layers, the second layer coupled to the first layer, wherein: a copper lining is between adjacent surfaces of any two adjacent dies in at least one of the first layer and the second layer, and the copper lining contacts and substantially covers the adjacent surfaces. In various embodiments, the dies comprise dummy dies and integrated circuit (IC) dies, the dummy dies are one of: semiconductor dies without any ICs, and semiconductor dies having non-functional ICs, and the IC dies comprise semiconductor dies having functional ICs.

### CROSS-REFERENCE TO RELATED APPLICATION

This application is a continuation of (and claims the benefit and priority under 35 U.S.C. 120 of) U.S. patent application Ser. No. 17/728,147 filed Apr. 25, 2022, entitled “PACKAGING ARCHITECTURE FOR WAFER-SCALE KNOWN-GOOD-DIE TO KNOWN-GOOD-DIE HYBRID BONDING,” the disclosure of which is considered part of, and is incorporated by reference in, the disclosure of this application.

### BACKGROUND

Electronic circuits when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a schematic cross-sectional view of an example microelectronic assembly according to some embodiments of the present disclosure.

FIG. 2 is a schematic cross-sectional view of another example microelectronic assembly according to some embodiments of the present disclosure.

FIG. 3A is a schematic top view of a portion of an example microelectronic assembly according to some embodiments of the present disclosure.

FIG. 3B is a schematic cross-sectional view of a portion of the example microelectronic assembly of FIG. 3A.

FIG. 4 is a schematic top view of a portion of another example microelectronic assembly according to some embodiments of the present disclosure.

FIGS. 5A-5F are schematic cross-sectional views of various stages of manufacture of an example microelectronic assembly according to some embodiments of the present disclosure.

FIGS. 6A-6D are schematic cross-sectional views of various stages of manufacture of an example microelectronic assembly according to some embodiments of the present disclosure.

FIGS. 7A-7D are schematic cross-sectional views of various stages of manufacture of an example microelectronic assembly according to some embodiments of the present disclosure.

FIG. 8 is a cross-sectional view of a device package that includes one or more microelectronic assemblies in accordance with any of the embodiments disclosed herein.

FIG. 9 is a cross-sectional side view of a device assembly that includes one or more microelectronic assemblies in accordance with any of the embodiments disclosed herein.

FIG. 10 is a block diagram of an example computing device that includes one or more microelectronic assemblies in accordance with any of the embodiments disclosed herein.

### DETAILED DESCRIPTION

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets. tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-chip (SOC). In other words, the individual dies are connected together to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall design separated into different dies, each one optimized in terms of design and manufacturing, the overall yield and cost of the combined die solution may be improved.

The connectivity between these dies is achievable by many different ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The silicon bridge and the 3D stacked architecture may also be combined, which allows for top-packaged chips to communicate with other chips horizontally using the silicon bridge and vertically, using Through-Mold Vias (TMVs) which are typically larger than TSVs. Yet another packaging architecture uses hybrid bonding processes to form high-density interconnects between stacks of dies in a true 3D configuration.

Currently, in such stacked 2.5D or 3D packaging architecture, dies are separately and individually attached to base dies to form the stack. Wafer-level processing cannot be performed because a single wafer may have more than one die that is non-functional; attaching such non-functional dies to a good die wastes resources and decreases overall manufacturing yield. Wafer to wafer hybrid bonding process can provide good bonding yields but cannot enable multiple KGD on top of a base die. Besides, wafer to wafer bonding processes cannot enable singulated die testing. Die to wafer hybrid bonding process is prone to defects due to foreign materials being introduced on bonding surface during dicing, chemical mechanical polishing, grinding, thinning, etc. Collective bonding of singulated dies on wafer can enable fast hybrid bonding but it is sensitive to defects from die singulation, thinning as well as die thickness variations. Cleaning of dies after singulation can mitigate some of the defects of die to wafer bonding, but while it is suitable in theory, in practice, it is difficult to achieve complete cleaning without damaging the bonding surfaces.

Accordingly, embodiments of the present disclosure provide a microelectronic assembly comprising a stack of layers coupled by at least fusion bonds (e.g., inorganic dielectric to inorganic dielectric bonds); a package substrate coupled to a first layer in the stack of layers; one or more dies in the first layer; and one or more dies in a second layer in the stack of layers, the second layer coupled to the first layer. A copper lining is between adjacent surfaces of any two adjacent dies in at least one of the first layer and the second layer, and the copper lining contacts and substantially covers the adjacent surfaces. The dies comprise KGDs and dummy dies in various embodiments.

Embodiments of the present disclosure also provide a method for fabricating a microelectronic assembly, the method comprising: reconstituting a first wafer with first IC dies and dummy dies; reconstituting a second wafer with second IC dies and dummy dies; coupling the reconstituted first wafer to the reconstituted second wafer by metal-metal bonds and fusion bonds; forming bond pads on the second IC dies; and dicing into individual microelectronic assemblies. Reconstituting the first wafer or the second wafer comprises forming a copper lining between adjacent and parallel surfaces of any two adjacent dies.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5 % tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 micrometers and 300 micrometers, while the DTD interconnects disclosed herein may have a pitch between about 0.5 micrometers and 100 micrometers, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

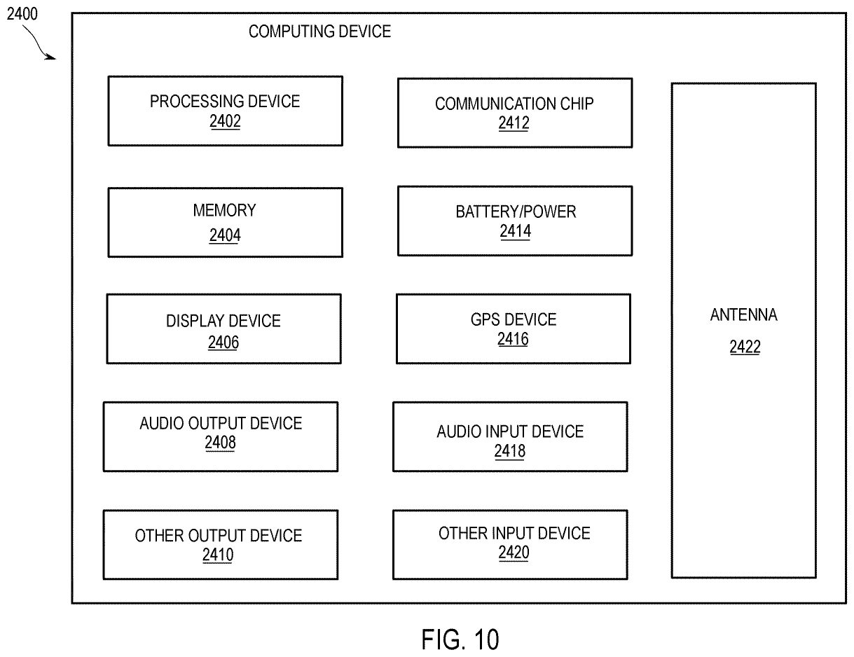

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

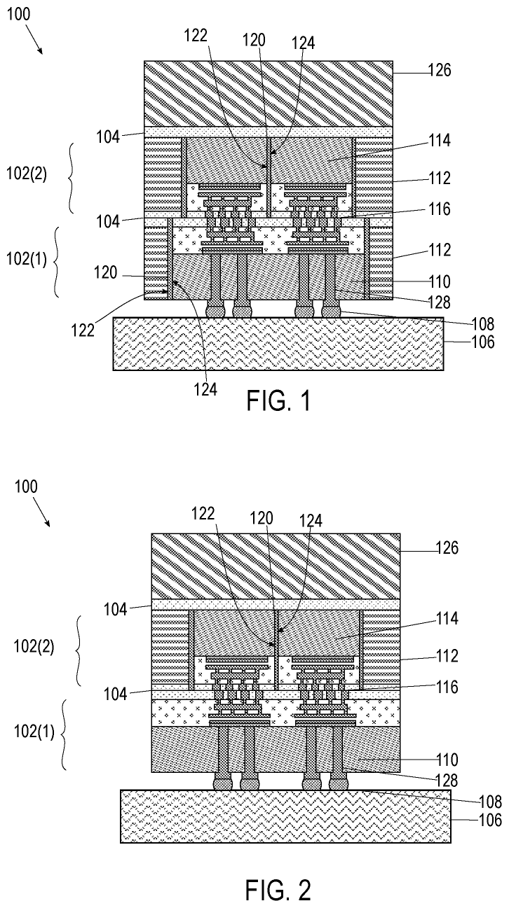

FIG. 1 is a schematic cross-sectional view of an example microelectronic assembly 100 according to some embodiments of the present disclosure. Microelectronic assembly 100, comprises, in the embodiment shown, a stack of layers 102 (e.g., 102(1), 102(2)) coupled face to face by at least fusion bonds 104 (e.g., oxide-oxide bonds). In some embodiments, fusion bonds 104 may include bonds between oxides, nitrides, carbides, oxy-nitrides, oxy-carbo-nitrides, etc. The term “fusion bond” as used herein is representative of bonds between a wide variety of inorganic materials typically encountered as dielectric materials in semiconductor processing. Microelectronic assembly 100 includes a package substrate 106 coupled to a particular layer (e.g., 102(1)) in the stack of layers by interconnects 108. In various embodiments, interconnects 108 may comprise DTPS interconnects as described in the previous section, having a pitch greater than 50 micrometers between adjacent interconnects 108. Package substrate 106 may comprise organic dielectric materials, or may be interposers having inorganic substrate materials, such as glass, ceramic, or semiconductor materials.

Layer 102(1) (or any other layer in stack of layers 102) comprises one or more dies, including IC dies 110 and dummy dies 112. IC dies 110 comprise functional ICs, i.e., IC dies 112 are KGDs. In a general sense, the KGD is typically a semiconductor die with ICs that have passed various testing operations, such as wafer probe, burn-in, functional test, screening, etc., and are operating within design parameters. The KGDs are manufactured in wafer form, singulated, tested (before or after singulation) and screened before being used in microelectronic assembly 100.

Dummy dies 112 are one of: semiconductor dies without any ICs, and semiconductor dies having non-functional ICs. In other words, dummy dies 112 may comprise a piece of silicon (or other solid material typically used as substates in semiconductor processing and as enumerated in the previous section) without any circuitry therein in some embodiments. In other embodiments, dummy dies 112 may comprise IC dies having non-functional ICs, for example, dies that have been binned as rejects from various manufacturing operations.

Layer 102(2) coupled to layer 102(1) comprises one or more dies including IC dies 114 and dummy dies 112. IC dies 114 comprise functional ICs, i.e., IC dies 114 are KGDs. In various embodiments, IC dies 114 comprise digital logic circuits (e.g., compute, random cache memory, etc.) of a microprocessor and IC dies 110 comprise other circuits (e.g., network-on-die circuit, power delivery network, physical layer interface (PHY) circuits, etc.) that enable the digital logic circuits of IC dies 114.

Dies in layer 102(2) are coupled to dies in layer 102(1) by metal-metal bonds 116, in addition to fusion bonds 104. Metal-metal bonds 116 and fusion bonds 104 may together be referred to as “hybrid bonds,” created at the interface between two adjacent and contacting layers (e.g., 102(1) and 102(2)). Conductive contacts disposed in one of the layers (e.g., in IC die 110 of layer 102(1)) may bond with conductive contacts disposed in the other layer (e.g., in IC die 114 of layer 102(2)) to form metal-metal bonds 116; likewise, the inorganic dielectric material (e.g., silicon oxide, silicon nitride, silicon oxynitride, etc.) in layer 102(1) may bond with the inorganic dielectric material in layer 102(2) to form fusion bonds 104. The bonded interconnects comprise hybrid bonds, providing electrical and structural coupling between layers 102(1) and 102(2). In various embodiments, metal-metal bonds 116 may have a pitch of less than 10 micrometers between adjacent metal-metal bonds 116. In various embodiments, dummy dies 112 (that do not have any metal bond pads) in any one layer 102 may be coupled to IC dies (e.g., 110, 114) or other dummy dies 112 in another layer by fusion bonds 104.

In some embodiments, dummy dies 112 may be absent in layer 102(1). The presence or absence of dummy dies 112 in layer 102(1) may be determined by the location of IC dies 114 over IC dies 110. For example, in embodiments wherein all IC dies 114 can be accommodated over IC dies 110 with sufficient space in IC dies 110 to dice therethrough from a wafer, dummy dies 112 may be absent in layer 102(1). Likewise, presence and location of dummy dies 112 in any layer 102 may be determined by the location of the other dies in respective layer 102. For example, dummy dies 112 may be present between any two IC dies 114 in layer 102(2) only where the spacing between the two IC dies 114 is greater than a minimum predetermined threshold. In some embodiments, the minimum predetermined threshold is approximately 500 micrometers.

By placing dummy dies 112 appropriately between IC dies 114 and/or IC dies 110, approximately uniform spacing may be obtained between any two adjacent dies. In various embodiments, a copper lining 120 is disposed in this approximately uniform spacing between adjacent and parallel surfaces 122 and 124 of any two adjacent dies. Copper lining 120 contacts and substantially covers adjacent surfaces 122 and 124 (i.e., extends through the thicknesses of the dies). In some embodiments, a passivation layer (e.g., silicon nitride) may coat adjacent surfaces 122 and 124, and copper lining 120 may contact this passivation layer. In various embodiments, adjacent surfaces 122 and 124 may belong respectively to adjacent IC die 110 and dummy die 112, two adjacent IC dies 110, two adjacent dummy dies 112, adjacent IC die 114 and dummy die 112, and two adjacent IC dies 114. In various embodiments, the spacing between the adjacent surfaces may be approximately, 10 micrometers such that copper lining 120 is approximately 10 micrometers wide.

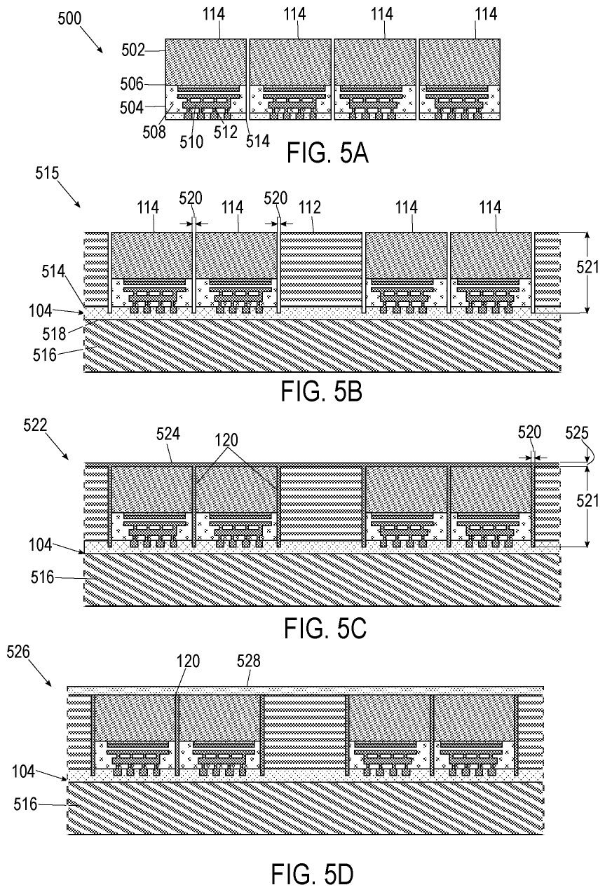

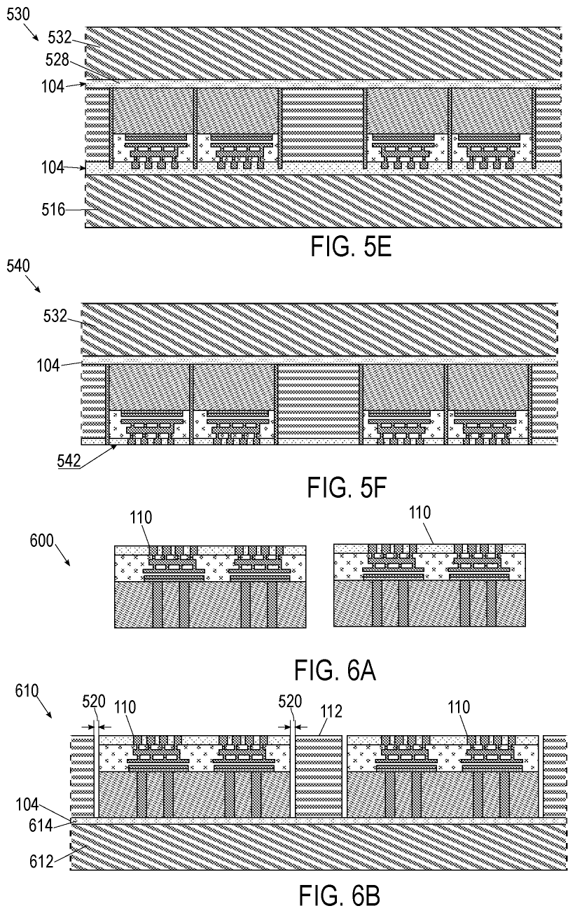

During manufacture of microelectronic assembly 100, KGDs (e.g., IC dies 110, 114) and dummy dies 112 are reconstituted on a carrier wafer leaving a gap of approximately 10 micrometers between adjacent dies. For example, IC dies 114 may be placed on the carrier wafer at locations corresponding to their connections with IC die 110; dummy dies 112 may be placed between IC dies 114 to create a uniform gap of approximately 10 micrometers between any two dies. The gaps are filled with copper plating using a variation of TSV copper plating process as described further below in reference to FIGS. 5-7. IC dies 114 are mounted on one carrier wafer with dummy dies 112 and IC dies 110 are mounted on another carrier wafer. By filling the gaps between dies with copper rather than an inorganic dielectric material, the surfaces of the two carrier wafers are amenable to be polished by chemical mechanical polishing (CMP) before bonding, thus providing high yields in wafer to wafer hybrid bonding processes. Embodiments of microelectronic assembly 100 can also facilitate aggregation of dies fabricated using different manufacturing processes (e.g., silicon nodes). For example, IC dies 110 may be fabricated using a first manufacturing process, and IC dies 114 may be fabricated using different and other manufacturing processes. Further, the configuration as described herein enables wafer to wafer bonding compatible with wafer-level tools.

In various embodiments, at least some dummy dies 112 may be located proximate to and/or along a periphery (e.g., boundary) of stack of layers 102 in any layer 102 such that when multiple ones of such microelectronic assembly 100 are fabricated on wafers, dicing into individual ones of microelectronic assembly 100 is performed through such dummy dies 112. In some embodiments, dummy dies 112 may also be placed in a medial region (e.g., toward a center) of microelectronic assembly 100. In general, dummy dies 112 may be placed wherever the spacing between adjacent IC dies (e.g., 110 or 114) exceeds the minimum predetermined threshold (e.g., 500 micrometers).

In various embodiments, a lid 126 of thermally conductive material (e.g., silicon) may be coupled to the stack of layers 102 on a side opposite to package substrate 106. In some embodiments, lid 126 may be coupled to the stack of layers 102 by fusion bonds 104. In some embodiments (not shown), lid 126 may be absent. In some embodiments, one or more of the dies may comprise TSVs 128. For example, in the embodiment shown, IC dies 110 comprise TSVs 128.

FIG. 2 is a schematic cross-sectional view of another example microelectronic assembly 100 according to some embodiments of the present disclosure. The embodiment shown in the figure is substantially similar to the embodiment of FIG. 1 except that dummy dies 112 in layer 102(1) are absent proximate to a periphery of microelectronic assembly 100. In such embodiments, individual ones of microelectronic assembly 100 are singulated from a wafer by dicing through IC die 110 in layer 102(1). Dummy dies 112 may be located in other layers (e.g., 102(2)).

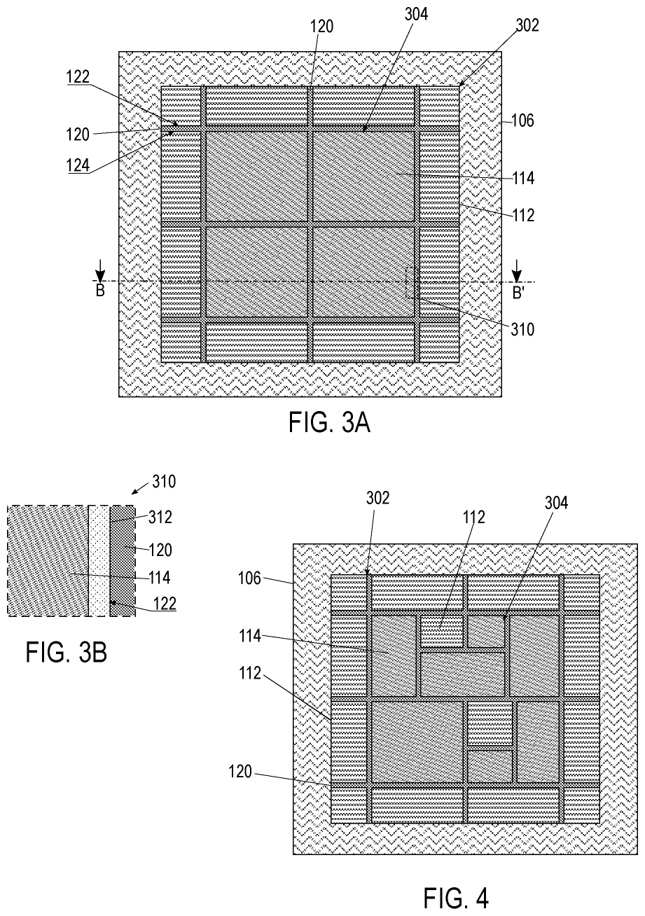

FIG. 3A is a schematic top view of a portion of an example microelectronic assembly 100 according to some embodiments of the present disclosure. In the embodiment shown, IC dies 114 (or 110) may be arranged in a grid or other uniform pattern in a medial region of microelectronic assembly 100. Although IC dies 114 in layer 102(2) are shown, the same configuration as described herein may be applied to IC dies 110 in layer 102(1) also without departing from the scope of the embodiments. Dummy dies 112 may be located proximate to a peripheral region 302 of microelectronic assembly 100. In the embodiment shown, dummy dies 112 are absent in a medial region 304 of microelectronic assembly 100. Thus, in the configuration shown, IC dies 114 are surrounded by dummy dies 112. Adjacent surfaces 122 and 124 of any two dies are separated by copper lining 120.

A cross-section taken at axis BB′ in a region 310 around copper lining 120 is shown in greater detail in FIG. 3B. A passivation layer 312 (e.g., silicon nitride) may coat surface 122 of IC die 114. Passivation layer 312 may extend substantially along the entire thickness (e.g., depth) of IC die 114, and across the entire area of surface 122. Copper lining 120 may contact passivation layer 312 (rather than the substrate material of the die), for example, preventing leaching of copper into the die. Similarly, surface 124 may also be coated with passivation layer 312; likewise, surfaces of dummy dies 112 may also be coated with passivation layer 312 as described.

FIG. 4 is a schematic top view of a portion of another example microelectronic assembly according to some embodiments of the present disclosure. The embodiment shown in the figure is substantially similar to the embodiment of FIG. 3A except that dummy dies 112 are present in medial region 304 and proximate to peripheral region 302. Although IC dies 114 in layer 102(2) are shown, the same configuration as described herein may be applied to IC dies 110 in layer 102(1) also without departing from the scope of the embodiments. As described previously, the location of dummy dies 112 may be determined by the layout of IC dies 114 on IC dies 110. Any possible arrangement of dies that can provide an approximately uniform gap of around 10 micrometers between adjacent dies may be included in the scope of the embodiments.

In various embodiments, any of the features discussed with reference to any of FIGS. 1-4 herein may be combined with any other features to form a package with one or more IC dies as described herein, for example, to form a modified microelectronic assembly 100. Some such combinations are described above, but, in various embodiments, further combinations and modifications are possible.

FIGS. 5A-5F are schematic cross-sectional views of various stages of manufacture of an example microelectronic assembly 100 according to some embodiments of the present disclosure. FIG. 5A shows a plurality 500 of IC dies 114. Each of IC dies 114 (as also any KGD, for example, IC die 110 in microelectronic assembly 100) comprises a substrate 502 and a metallization stack 504 with an active region 506 between substrate 502 and metallization stack 504. Metallization stack 504 comprises a plurality of layers of interlayer dielectric (ILD) material 508 and conductive traces 510 connected by conductive vias 512 through ILD material 508. Various active components such as diodes and transistors are in active region 506 between substrate 502 and metallization stack 504. In some embodiments (not shown) IC dies 114 (and/or IC dies 110) may also comprise TSVs 128. IC dies 114 are KGDs, that is, they have passed various testing operations so that it is known that they have no substantial defects, and they conform to design specifications. Each IC die 114 may have an oxide layer 514 on a side of metallization stack 504 that is opposite to substrate 502.

FIG. 5B shows an assembly 515 after assembly on a carrier 516. In some embodiments, carrier 516 may be a wafer. In some other embodiments, carrier 516 may be a panel (e.g., glass or ceramic). Carrier 516 may be coated with an oxide layer 518. IC dies 114 and dummy dies 112 may be picked and placed on carrier 516 leaving a gap 520 between any two adjacent dies. Note that only two gaps are labeled as such merely for ease of illustration and so as not to clutter the drawing. In various embodiments, gap 520 may be approximately 10 micrometers in width and may have a depth 521 of approximately 100 micrometers (i.e., in embodiments IC dies 114 and dummy dies 112 are approximately 100 micrometers thick). Thus, gaps 520 have a high aspect ratio of 1:10 (or greater). IC dies 114 and dummy dies 112 may be placed on carrier 516 such that oxide layer 514 of IC dies 114 and dummy dies 112 are in contact with oxide layer 518 of carrier 516. The assembly may be subject to high temperature (and/or pressure) such that oxide layers 514 and 518 bond to form fusion bonds 104.

FIG. 5C shows an assembly 522 after further operations on assembly 515. In some embodiments (not shown), a layer of silicon nitride of approximately 1 micrometer in width (or thickness) may be conformally coated over assembly 515. The silicon nitride coating may fill the walls and bottoms of gaps 520 in addition to coating surfaces (parallel to carrier 516) of IC dies 114 and dummy dies 112. Thereafter, copper 524 may be deposited on assembly 515, coating IC dies 114 and dummy dies 112 and filling gaps 520.

In some embodiments, copper 524 is deposited using electrochemical deposition (ECD) with a plating solution. The particular chemical composition and other parameters of the ECD process are beyond the scope of the embodiments discussed here and as such, are well known in the art for producing TSVs in semiconductor substrates. For example, various levels of chlorine ion, suppresser and accelerants can influence the thickness, location of deposition, and speed of deposition of copper 524 on the dies. High aspect ratio vias such as gaps 520 may be filled with copper using a suitable balance of electrolyte composition, solution replenishment, and applied voltage as is known in the art. For example, using a copper sulfate-sulfuric acid (CuSO₄—H₂SO₄) electrolyte containing a suppressor and a low chloride concentration, a tunable relationship between applied voltage and localized deposition in the vias may be achieved. A stepped (e.g., pulsed) potential waveform may be applied to move the copper growth front from the bottom of gap 520 to the top. Other methods may also be used as appropriate to achieve the desired structure. Gaps 520 are filled with copper 524 substantially throughout depth 521 (thereby forming copper lining 120), whereas only a relatively thin coating of thickness 525 is formed on surfaces (parallel to carrier 516) of IC dies 114 and dummy dies 112. Thus depth 521 of copper 524 is much larger than thickness 525 on surfaces parallel to carrier 516.

FIG. 5D shows an assembly 526 after further operations on assembly 522. Copper 524 coating surfaces (parallel to carrier 516) of IC dies 114 and dummy dies 112 may be removed using any suitable etching or other process known in the art. An oxide coating 528 may be applied over IC dies 114 and dummy dies 112 thereafter.

FIG. 5E shows an assembly 530 after further operations on assembly 522. Another carrier 532 may be bonded to assembly 522 over oxide coating 528 forming fusion bonds 104.

FIG. 5F shows an assembly 540 after further operations on assembly 530. Carrier 516 may be removed, for example, by dicing, grinding, and/or CMP until bond pads of IC dies 114 are exposed on surface 542. Surface 542 may thereafter be subject to cleaning operations.

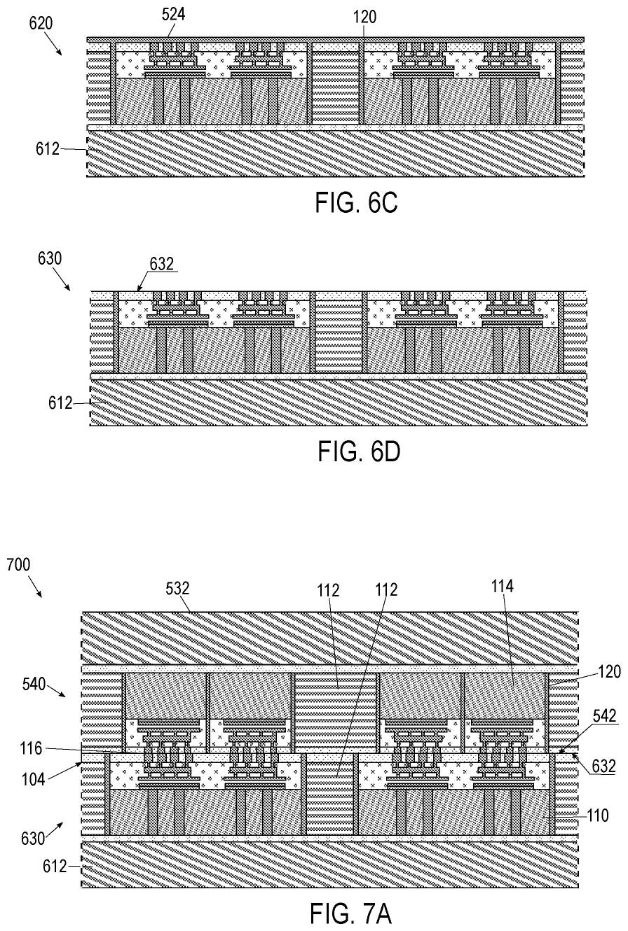

FIGS. 6A-6D are schematic cross-sectional views of various stages of manufacture of an example microelectronic assembly 100 according to some embodiments of the present disclosure. FIG. 6A shows a plurality 600 of IC dies 110. As discussed previously, IC dies 110 are KGDs.

FIG. 6B shows an assembly 610 after further operations. Plurality of IC dies 110 and dummy dies 112 may be assembled on a carrier 612. Carrier 612 may be substantially identical to carrier 516 in various embodiments. IC dies 110 and dummy dies 112 may be coated with an oxide layer (not shown) before being picked and placed on carrier 612 leaving gap 520 between any two adjacent dies. In various embodiments, gap 520 may be approximately 10 micrometers in width and approximately 100 micrometers in depth. The oxide layer on IC dies 110 and dummy dies 112 may bond with an oxide layer 614 of carrier 612 to create fusion bonds 104.

FIG. 6C shows an assembly 620 after further operations on assembly 610. In some embodiments (not shown), a layer of silicon nitride of approximately 1 micrometer in thickness (or width) may be conformally coated over assembly 610. The silicon nitride coating may fill the walls and bottoms of gaps 520 in addition to coating surfaces (parallel to carrier 612) of IC dies 110 and dummy dies 112. Thereafter, copper 524 may be deposited on assembly 610, coating IC dies 110 and dummy dies 112 and filling gaps 520. As discussed previously in relation to FIG. 5C, copper 524 may be deposited such that gaps 520 are filled substantially completely whereas only a relatively thinner layer is formed over surfaces of IC dies 110 and dummy dies 112 parallel to carrier 612.

FIG. 6D shows an assembly 630 after further operations on assembly 620. The relatively thin layer of copper formed over surfaces of IC dies 110 and dummy dies 112 parallel to carrier 612 may be removed, for example, by etching or CMP, exposing metal bond pads of IC dies 110 on a surface 632.

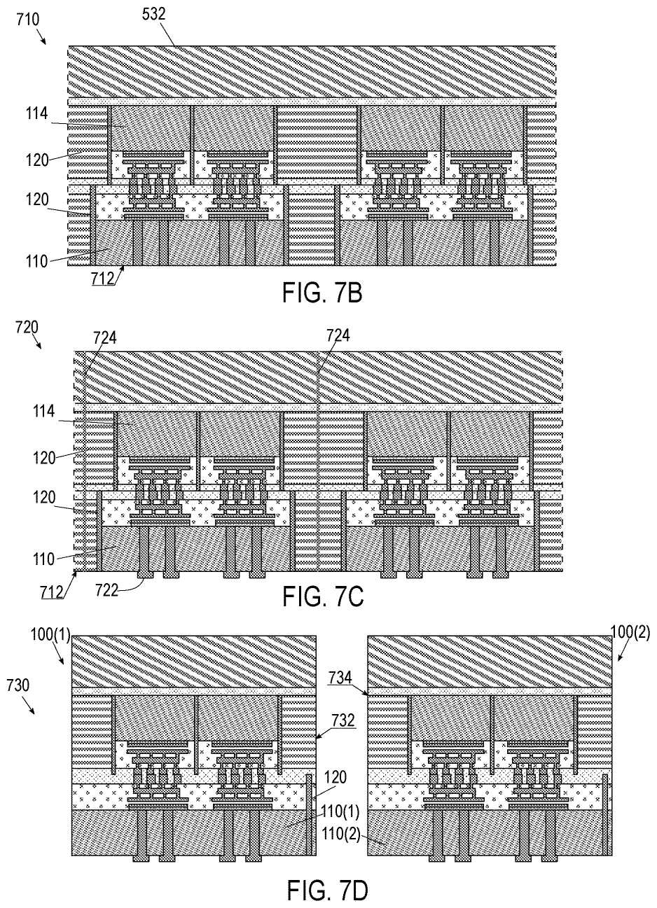

FIGS. 7A-7D are schematic cross-sectional views of various stages of manufacture of an example microelectronic assembly according to some embodiments of the present disclosure. FIG. 7A shows an assembly 700 after coupling assemblies 540 and 630. Surface 542 of assembly 540 is brought in contact with surface 632 of assembly 630 and subjected to high temperature and pressure to form metal-metal bonds 116 between IC dies 110 and IC dies 114 and fusion bonds 104. In some embodiments, dummy dies 112 in multiple layers 102 that are configured to be located along boundaries (or proximate to peripheral regions 302) of individual microelectronic assemblies 100 may be aligned one on top of another as shown.

FIG. 7B shows an assembly 710 after further operations on assembly 700. Carrier 612 coupled to IC dies 110 may be removed, for example, by dicing, grinding and/or CMP to expose surface 712 having contact surfaces of TSVs 128 where applicable.

FIG. 7C shows an assembly 720 after further operations on assembly 710. Bond pads 722 may be plated or otherwise deposited on surface 712 over the contact surfaces of TSVs. Bond pads 722 may be used to bond microelectronic assembly 100 to package substrate 106 by interconnects 108. In some embodiments (not shown) suitable redistribution layers (RDLs) may be formed on surface 712. Thereafter, individual ones of microelectronic assembly 100 may be formed by dicing through scribe region 724. Scribe region 724 represents a space in assembly 720 through which a dicing-saw or other cutting equipment passes, severing assembly 720 into pieces, each piece comprising an individual one of microelectronic assembly 100. In various embodiments, scribe region 724 passes through some dummy dies 112 so that when severed, such dummy dies 112 are located proximate to the periphery of each microelectronic assembly 100. In some embodiments, scribe region 724 may pass through IC dies 110. In such embodiments, scribe region 724 through IC dies 110 may not pass through copper lining 120, but rather passes through the body of IC dies 110.

FIG. 7D shows a plurality 730 of microelectronic assemblies 100(1) and 100(2) after further dicing and separating from wafer form. In the embodiment shown, there are no dummy dies 112 in the layer comprising IC dies 110. In other words, adjacent IC dies 110 are separated by copper lining 120 only. In such embodiments, scribe region 724 passes through IC dies 110 such copper lining 120 may be retained in one IC die 110 and not in its adjacent counterpart. For example, microelectronic assembly 100(1) comprises IC die 110(1) and microelectronic assembly 100(2) comprises IC die 110(2). Dicing through scribe region 724 separates microelectronic assemblies 100(1) and 100(2), creating surface 732 on microelectronic assembly 100(1) and surface 734 on microelectronic assembly 100(2). Copper lining 120 may be retained within IC die 110(1), to the left of surface 732 in reference to the figure, and therefore, copper lining 120 may be absent in IC die 110(2) proximate to and to the right of surface 734 in reference to the figure. In other words, a portion of IC die 110(2) may be retained in microelectronic assembly 100(1) by the dicing operation.

The processes as shown and described in reference to FIGS. 5-7 may be repeated to get more than two layers in the stack of layers 102. In the embodiments shown, IC dies 114 are shown bonded face to face with IC dies 110. In other embodiments, IC dies 114 may be bonded face to back, or back to back with IC dies 110. In such embodiments, appropriate operations for creating fusion bonds 104 and metal-metal bonds 116 may be added to the operations as appropriate.

Although FIGS. 5-7 illustrate various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIGS. 5-7 may be modified in accordance with the present disclosure to fabricate others of microelectronic package 100 disclosed herein. Although various operations are illustrated in FIGS. 5-7 once each, the operations may be repeated as often as desired. For example, one or more operations may be performed in parallel to manufacture multiple microelectronic packages substantially simultaneously. In another example, the operations may be performed in a different order to reflect the structure of a particular microelectronic package in which one or more substrates or other components as described herein may be included.

Furthermore, the operations illustrated in FIGS. 5-7 may be combined or may include more details than described. Still further, the various operations shown and described may further include other manufacturing operations related to fabrication of other components of the microelectronic assemblies described herein, or any devices that may include the microelectronic assemblies as described herein. For example, the operations not shown in FIGS. 5-7 may include various cleaning operations, additional surface planarization operations, operations for surface roughening, operations to include barrier and/or adhesion layers as desired, and/or operations for incorporating microelectronic packages as described herein in, or with, an IC component, a computing device, or any desired structure or device.

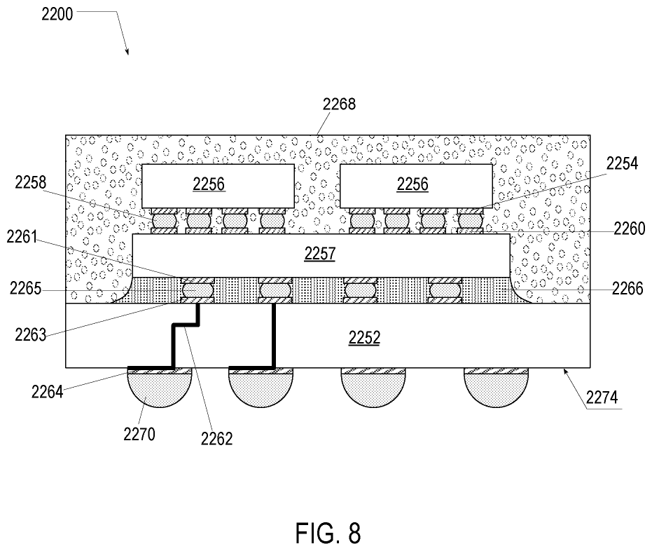

The packages disclosed herein, e.g., any of the embodiments shown in FIGS. 1-7 or any further embodiments described herein, may be included in any suitable electronic component. FIGS. 8-10 illustrate various examples of packages, assemblies, and devices that may be used with or include any of the IC packages as disclosed herein.

FIG. 8 is a side, cross-sectional view of an example IC package 2200 that may include IC packages in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

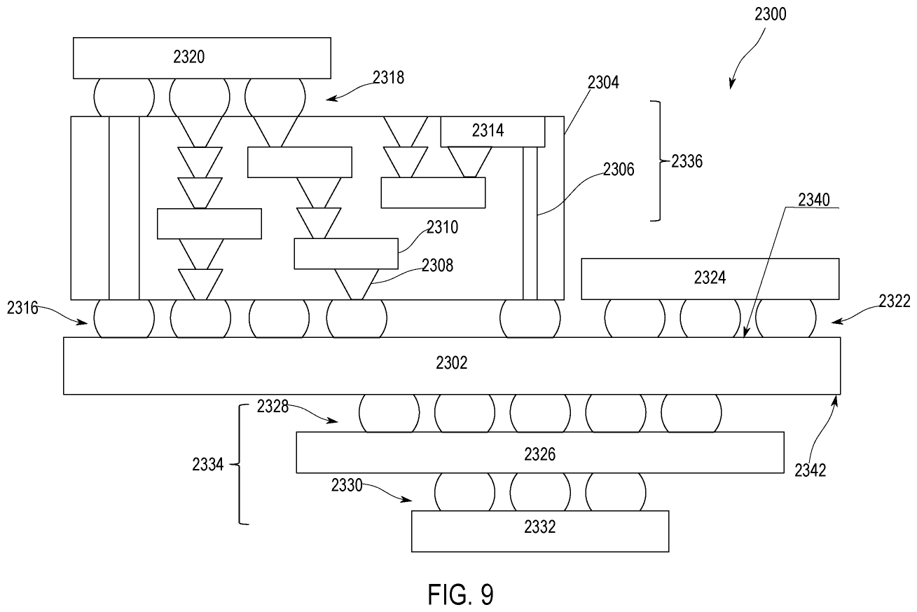

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 9.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 9 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 8.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 8. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 10 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 8). In yet another example, any one or more of the components of computing device 2400 may include an IC device assembly 2300 (e.g., as shown in FIG. 9).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

The following paragraphs provide various examples of the embodiments disclosed herein.
Example 1 provides a microelectronic assembly (e.g., 100), comprising (e.g., FIG. 1): a stack of layers (e.g., 102(1), 102(2)) comprising dies, adjacent layers being coupled by at least fusion bonds (e.g., 104); a package substrate (e.g., 106) coupled to a first layer (e.g., 102(1)) in the stack of layers; one or more dies (e.g., 110, 112) in the first layer; and one or more dies (e.g., 112, 114) in a second layer (e.g., 102(2)) in the stack of layers, the second layer coupled to the first layer, in which: a copper lining (e.g., 120) is between adjacent surfaces (e.g., 122, 124) of any two adjacent dies in at least one of the first layer and the second layer, and the copper lining contacts and substantially covers the adjacent surfaces.
Example 2 provides the microelectronic assembly of example 1, in which the copper lining is approximately 10 micrometers wide.
Example 3 provides the microelectronic assembly of any one of examples 1-2, in which the fusion bonds comprise oxide-oxide bonds.
Example 4 provides the microelectronic assembly of any one of examples 1-3, in which: a compound comprising silicon and nitrogen (e.g., 312) coats the adjacent surfaces, and the copper lining is in contact with the compound.
Example 5 provides the microelectronic assembly of any one of examples 1-4, in which: the dies comprise dummy dies (e.g., 112) and integrated circuit (IC) dies (e.g., 110, 114), the dummy dies are one of: semiconductor dies without any ICs, and semiconductor dies having non-functional ICs, and the IC dies comprise semiconductor dies having functional ICs.
Example 6 provides the microelectronic assembly of example 5, in which: each of the IC dies comprises a substrate (e.g., 502) and a metallization stack (e.g., 504), an active region (e.g., 506) is between the substrate and the metallization stack, the metallization stack comprises a plurality of layers of interlayer dielectric (ILD) material (e.g., 508) and conductive traces (e.g., 510) connected by conductive vias (e.g., 512) through the ILD material.
Example 7 provides the microelectronic assembly of any one of examples 5-6, in which: the IC dies in the second layer comprise digital logic circuits of a microprocessor, and the IC dies in the first layer comprise circuits that enable the digital logic circuits.
Example 8 provides the microelectronic assembly of any one of examples 5-7, in which a subset of the dummy dies is proximate to a peripheral region (e.g., 302) of the microelectronic assembly.
Example 9 provides the microelectronic assembly of example 8, in which a portion of the subset of the dummy dies is in the second layer.
Example 10 provides the microelectronic assembly of example 9, in which another portion of the subset of the dummy dies is in the first layer.
Example 11 provides the microelectronic assembly of any one of examples 8-10, in which (e.g., FIG. 4) another subset of the dummy dies is in a medial region (e.g., 304) of the microelectronic assembly.
Example 12 provides the microelectronic assembly of example 11, in which a portion of the another subset of the dummy dies is in the second layer.
Example 13 provides the microelectronic assembly of example 12, in which another portion of the another subset of the dummy dies is in the first layer.
Example 14 provides the microelectronic assembly of any one of examples 11-13, in which the dummy dies in the another subset are located between two IC dies that are spaced at least 500 micrometers apart.
Example 15 provides the microelectronic assembly of any one of examples 1-14, in which the package substrate is coupled to the stack of layers by die-to-package substrate (DTPS) interconnects (e.g., 108).
Example 16 provides the microelectronic assembly of any one of examples 1-15, in which the one or more dies in the first layer are coupled to the one or more dies in the second layer by metal-metal bonds (e.g., 116) having a pitch of less than 10 micrometers between adjacent ones of the metal-metal bonds.
Example 17 provides the microelectronic assembly of any one of examples 1-16, further comprising a lid (e.g., 126) of thermally conductive material coupled to the stack of layers on a side opposite to the package substrate.
Example 18 provides the microelectronic assembly of example 17, in which the lid is coupled to the stack of layers by fusion bonds.
Example 19 provides the microelectronic assembly of any one of examples 17-18, in which the second layer is between the lid and the first layer.
Example 20 provides the microelectronic assembly of any one of examples 17-19, further comprising additional layers of dies between the lid and the second layer.
Example 21 provides the microelectronic assembly of any one of examples 1-20, in which the one or more dies in the first layer or the second layer comprises through-substrate vias (TSVs) (e.g., 128).
Example 22 provides an IC package, comprising: a first plurality of dies (e.g., 110); a second plurality of dies (e.g., 114) coupled to the first plurality of dies; and a package substrate (e.g., 106) coupled to the first plurality of dies, in which: the first plurality of dies is between the second plurality of dies and the package substrate, a copper lining (e.g., 120) is between adjacent surfaces (e.g., 122, 124) of any two adjacent dies in the first plurality of dies or the second plurality of dies, and the copper lining contacts and substantially covers the adjacent surfaces.
Example 23 provides the IC package of example 22, in which: the dies comprise one or more dummy dies and one or more IC dies, the dummy dies are one of: semiconductor dies without any integrated circuits, and semiconductor dies having non-functional integrated circuits, and the IC dies comprise semiconductor dies with functional integrated circuits (e.g., known good dies).
Example 24 provides the IC package of example 23, in which: the second plurality of dies comprises the dummy dies, and the first plurality of dies does not comprise any of the dummy dies.
Example 25 provides the IC package of any one of examples 23-24, in which: a first subset in the second plurality of dies comprises IC dies, the IC dies in the first subset are coupled to a medial region of one of the dies in the first plurality of dies, a second subset in the second plurality of dies comprises dummy dies coupled to a peripheral region of the one of the dies in the first plurality of dies.
Example 26 provides the IC package of any one of examples 22-25, in which the dies are approximately 100 micrometers thick.
Example 27 provides the IC package of any one of examples 22-26, in which: more than one die in the second plurality of dies is coupled to one of the dies in the first plurality of dies, and the coupling is by metal-metal bonds and fusion bonds.
Example 28 provides the IC package of any one of examples 22-27, in which: dies in the first plurality of dies or the second plurality of dies are not more than 10 micrometers apart, and a dummy die is located in any space larger than approximately 500 micrometers between adjacent IC dies.
Example 29 provides the IC package of any one of examples 22-28, in which the copper lining is approximately 10 micrometers wide.
Example 30 provides the IC package of any one of examples 22-29, in which surfaces of the dies in contact with the copper lining have a coating of a compound comprising silicon and nitrogen.
Example 31 provides the IC package of any one of examples 22-30, further comprising a lid of thermally conductive material coupled to the second plurality of dies by fusion bonds.
Example 32 provides a method for fabricating a microelectronic assembly, the method comprising (e.g., FIGS. 5-7): reconstituting a first wafer with first IC dies (e.g., 114) and dummy dies (e.g., 112), in which the dummy dies are one of: semiconductor dies without any integrated circuits therein, and semiconductor dies having non-functional integrated circuits therein (e.g., FIGS. 5A-5F); reconstituting a second wafer with second IC dies (e.g., 110) and dummy dies (e.g., 112) (e.g., FIGS. 6A-6D); coupling the reconstituted first wafer to the reconstituted second wafer by metal-metal bonds and fusion bonds (e.g., FIG. 7A); forming bond pads on the second IC dies (e.g., FIG. 7C); and dicing into individual microelectronic assemblies (e.g., FIG. 7D).
Example 33 provides the method of example 32, in which reconstituting the first wafer comprises (e.g., FIGS. 5A-5F): providing a plurality of dies, the dies comprising the first IC dies and the dummy dies (e.g., FIG. 5A); coupling the plurality of dies to a first carrier (e.g., 516, FIG. 5B) such that any two dies are separated by a gap (e.g., 520); depositing copper (e.g., 524) over the dies, in which the copper fills the gaps and coats surfaces of the dies opposite to the first carrier (e.g., FIG. 5C); removing the copper over the surfaces of the dies opposite to the first carrier (e.g., FIG. 5D); depositing oxide (e.g., 526) over the dies (e.g., FIG. 5D); coupling a second carrier (e.g., 532) to the oxide (e.g., FIG. 5E); and removing the first carrier (e.g., FIG. 5F).
Example 34 provides the method of example 33, in which coupling the plurality of dies to the first carrier comprises forming fusion bonds (e.g., 104) between the dies and the first carrier.
Example 35 provides the method of any one of examples 33-34, in which the gap is approximately 10 micrometers.
Example 36 provides the method of any one of examples 33-35, further comprising, before depositing the copper, depositing a compound comprising silicon and nitrogen over the dies, such that the compound coats adjacent surfaces of the dies.
Example 37 provides the method of any one of examples 33-36, in which removing the copper over the surfaces of the dies comprises chemical mechanical polishing (CMP).
Example 38 provides the method of any one of examples 33-37, in which coupling the second carrier to the oxide comprises forming fusion bonds between the second carrier and the oxide.
Example 39 provides the method of any one of examples 32-38, in which reconstituting the second wafer comprises (e.g., FIGS. 5A-5F): providing a plurality of dies, the dies comprising the second IC dies (e.g., 110) and the dummy dies (e.g., FIG. 6A); coupling the plurality of dies to a carrier (e.g., 612, FIG. 6B) such that any two dies are mutually separated by a gap (e.g., 506); depositing copper (e.g., 512) over the dies, in which the copper fills the gaps and coats surfaces of the dies opposite to the carrier (e.g., FIG. 6C); and removing the copper over the surfaces of the dies opposite to the carrier (e.g., FIG. 6D) to expose a surface (e.g., 632) of the reconstituted second wafer.
Example 40 provides the method of example 39, in which the reconstituted first wafer is coupled to the exposed surface of the reconstituted second wafer.
Example 41 provides the method of any one of examples 39-40, in which coupling the plurality of dies to the carrier comprises forming fusion bonds (e.g., 104) between the dies and the carrier.
Example 42 provides the method of any one of examples 32-41, in which the metal-metal bonds are between the first IC dies and the second IC dies.
Example 43 provides the method of any one of examples 32-42, in which the dicing is performed through a scribe region.
Example 44 provides the method of example 43, in which the scribe region in the reconstituted first wafer is in at least some of the dummy dies in the reconstituted first wafer.
Example 45 provides the method of any one of examples 43-44, in which the scribe region in the reconstituted second wafer is in at least some of the dummy dies in the reconstituted second wafer.
Example 46 provides the method of any one of examples 43-44, in which the scribe region in the reconstituted second wafer is in at least some of the second IC dies.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a package substrate;
a stack of dies over the package substrate, the stack of dies comprising a first die over the package substrate and a second die over the first die;
die-to-package substrate (DTPS) interconnects between the package substrate and the stack of dies;
a first bonding layer, the first bonding layer comprising first metal contacts and a first dielectric material surrounding at least portions of sidewalls of the first metal contacts; and
a second bonding layer, the second bonding layer comprising second metal contacts and a second dielectric material surrounding at least portions of sidewalls of the second metal contacts,
wherein:
the first die includes a substrate, a first layer comprising transistors, and a first metallization stack comprising first conductive traces,
the first layer is between the substrate and the first metallization stack,
the first metallization stack is between the substrate and the first bonding layer,
the second die includes a silicon layer, a second layer comprising transistors, and a second metallization stack comprising second conductive traces,
the second layer is between the second metallization stack and the silicon layer,
the second die includes memory circuitry,
the second bonding layer is between the first bonding layer and the second metallization stack,
the first bonding layer is between the first metallization stack and the second bonding layer,
the first dielectric material is in contact with the second dielectric material,
one of the first metal contacts is in contact with one of the second metal contacts,
the one of the first metal contacts is misaligned with respect to the one of the second metal contacts,
a volume of the one of the first metal contacts is larger than a volume of the one of the second metal contacts, and
a pitch of the second metal contacts is between 0.5 micrometers and 100 micrometers.

2. The microelectronic assembly according to claim 1, wherein the pitch of the second metal contacts is smaller than 10 micrometers.

3. The microelectronic assembly according to claim 1, wherein the first metal contacts include copper.

4. The microelectronic assembly according to claim 1, wherein the second metal contacts include copper.

5. The microelectronic assembly according to claim 1, wherein the first dielectric material includes silicon and nitrogen.

6. The microelectronic assembly according to claim 1, wherein the second dielectric material includes silicon and nitrogen.

7. The microelectronic assembly according to claim 1, wherein the DTPS interconnects include solder.

8. The microelectronic assembly according to claim 1, wherein the DTPS interconnects include solder balls.

9. The microelectronic assembly according to claim 1, wherein:
another one of the first metal contacts is in contact with another one of the second metal contacts, and
the another one of the first metal contacts is misaligned with respect to the another one of the second metal contacts.

10. The microelectronic assembly according to claim 9, wherein:
a volume of the another one of the first metal contacts is larger than a volume of the another one of the second metal contacts.

11. The microelectronic assembly according to claim 1, further comprising:
a third die coplanar with the second die,
wherein:
the third die includes another silicon layer, a third layer comprising transistors, and a third metallization stack comprising third conductive traces, and
the third layer is between the third metallization stack and the another silicon layer.

12. The microelectronic assembly according to claim 11, wherein the third die includes another memory circuitry.

13. The microelectronic assembly according to claim 11, wherein the third die is coupled with the first die.

14. A microelectronic assembly, comprising:
a package substrate;
a first die over the package substrate, the first die including a substrate, a first layer comprising transistors, and a first metallization stack comprising conductive lines;
a second die over the first die, the second die including a layer comprising silicon, a second layer comprising transistors, and a second metallization stack comprising conductive lines, wherein the second die includes memory cells;
a first bonding layer comprising first metal contacts and a first dielectric material surrounding at least portions of the first metal contacts; and
a second bonding layer comprising second metal contacts and a second dielectric material surrounding at least portions of the second metal contacts,
wherein:
the first layer is between the substrate and the first metallization stack,
the first metallization stack is between the first layer and the first bonding layer,
the first bonding layer is between the first metallization stack and the second bonding layer,
the second bonding layer is between the first bonding layer and the second metallization stack,
the second metallization stack is between the second bonding layer and the second layer,
the second layer is between the second metallization stack and the layer comprising silicon,
the first dielectric material interfaces the second dielectric material,
individual ones of the first metal contacts are in contact with individual ones of the second metal contacts,
the first metal contacts and the second metal contact include copper, and
the first dielectric material and the second dielectric material include silicon and nitrogen.

15. The microelectronic assembly according to claim 14, wherein a pitch of the first metal contacts is between 0.5 micrometers and 100 micrometers.

16. The microelectronic assembly according to claim 15, further comprising:
conductive interconnects between the package substrate and one or both of the first die and the second die,
wherein a pitch of the conductive interconnects is greater than the pitch of the first metal contacts.

17. The microelectronic assembly according to claim 14, wherein:
one of the first metal contacts is in contact with one of the second metal contacts, and
the one of the first metal contacts is misaligned with respect to the one of the second metal contacts.

18. The microelectronic assembly according to claim 14, wherein:
one of the first metal contacts is in contact with one of the second metal contacts, and
a width of the one of the first metal contacts is larger than a width of the one of the second metal contacts.

19. An integrated circuit (IC) package, comprising:
a circuit board;
a package substrate over the circuit board, the package substrate comprising electrical traces;
electrical connections between the circuit board and the package substrate;
a first die over the package substrate, the first die including a first face, a second face opposite the first face, a first layer comprising transistors, and a second layer comprising conductive interconnects, wherein the first layer is between the second layer and the first face, and the second layer is between the second face and the first layer;
a second die over the package substrate, the second die including a third face, a fourth face opposite the third face, a third layer comprising transistors, and a fourth layer comprising conductive interconnects, wherein the third layer is between the third face and the fourth layer, the fourth layer is between the third layer and the fourth face, a bulk semiconductor region of the second die is between the third face and the fourth layer, and the fourth face faces the second face;
a third die over the package substrate, the third die including a fifth face and a sixth face opposite the fifth face, a fifth layer comprising transistors, and a sixth layer comprising conductive interconnects, wherein the third die is adjacent to the first die in a direction parallel to the fourth face, the fifth layer is between the sixth layer and the fifth face, and the sixth layer is between the sixth face and the fifth layer;
a first bonding layer between the second face and the fourth face, the first bonding layer including first metal contacts therein; and
a second bonding layer between the second face and the fourth face, wherein the second bonding layer includes second metal contacts therein, the first bonding layer is in direct contact with the second bonding layer, and ones of the first metal contacts are in direct contact with ones of the second metal contacts.

20. The IC package according to claim 19, wherein the third die is coplanar with the first die.
